(19) United States
(12) Patent Application Publication
(10) Pub. No.: US 2020/0170106 A1
(43) Pub. Date: May 28, 2020

(54) FLEXIBLE CIRCUIT BOARD PROTECTION LAYER AND OLED DISPLAY DEVICE

(71) Applicant: Wuhan China Star Optoelectronics Semiconductor Display Technology Co., Ltd., Wuhan, Hubei (CN)

(72) Inventor: Jiashu WU, Wuhan, Hubei (CN)

(21) Appl. No.: 15/777,174

(22) PCT Filed: Feb. 22, 2018
(86) PCT No.: PCT/CN2018/076948

§ 371 Date: May 17, 2018

(30) Foreign Application Priority Data
Dec. 29, 2017 (CN) 201711484135.X

(51) Int. Cl. H05K 1/02; H01L 27/32; H05K 1/18

(52) U.S. Cl. CPC H05K 1/0281; H01L 27/3276; H05K 2201/2009; H05K 1/189; H05K 2201/10128; H01L 27/3288

(57) ABSTRACT

A flexible circuit board protection layer includes a flexible backing, a first flexible layer arranged on one side of the flexible backing, and a second flexible layer arranged on one side of the first flexible layer that is distant from the flexible backing. The first flexible layer includes first strip sections that are arranged parallel and spaced from each other. The second flexible layer includes second strip sections that are arranged parallel and spaced from each other. The first strip sections have an extension direction that is perpendicular to an extension direction of the second strip sections. To use in an OLED display device, the flexible circuit board is arranged between two such flexible circuit board protection layers and then disposed on one side of the display panel in order effectively protect the flexible circuit board and prevent the flexible circuit board from being damaged during flexing.

### BACKGROUND OF THE INVENTION

### 1. Field of the Invention

The present invention relates to the field of display technology, and more particular to a flexible circuit board protection layer and an organic light emitting display (OLED) device.

### 2. The Related Arts

Organic light-emitting display (OLED) devices possess various advantages, such as being self-luminous, low drive voltage, high luminous efficiency, short response time, high clarity and contrast, almost 180° view angle, wide range of operation temperature, and easy realization of flexible displaying and large-area full-color displaying, and are considered the most promising display devices.

Based on the way of driving, OLEDs can be classified in two categories, passive matrix OLED (PMOLED) and active matrix OLED (AMOLED), namely one for direct addressing, and the other for TFT array addressing, among which, the AMOLED comprises pixels that are arranged in an array and belongs to an active display type, having high light emission performance and being commonly used in high definition large-sized display devices.

An OLED device is generally made up of a substrate, an anode arranged on the substrate, a hole injection layer arranged on and anode, a hole transport layer arranged on the hole injection layer, an emissive layer arranged on the hole transport layer, an electron transport layer arranged on the emissive layer, an electron injection layer arranged on the electron transport layer, and a cathode arranged on the electron injection layer. The principle of light emission of an OLED display device is that when a semiconductor material and an organic light emission material are driven by an electric field, carrier currents are injected and re-combine to cause emission of light. Specifically, the OLED display device often uses an indium tin oxide (ITO) pixel electrode and a metal electrode to respectively serve as the anode and cathode of the device and electrons and holes, when driven by a predetermined electrical voltage, are respectively injected into the electron transport layer and the hole transport layer such that the electrons and the holes respectively migrate through the electron transport layer and the hole transport layer to get into the emissive layer and meet in the emissive layer to form excitons that excites light emissive molecules to emit light, the later undergoing radiation relaxation to give off visible light.

In the known design structure of flexible AMOLED display devices, to suit the needs for slim frames, the area of a display panel that is bonded to a flexible circuit is flexed in order to reduce the surface area of a non-display zone in order to achieve the purpose of high screen ratio. However the area where the flexible circuit board is bonded, once flexed, may readily cause tiny cracking and circuit breaking or peeling. Also, such a portion may readily cause tiny cracking or peeling during product fabrication or shipping process due to insufficiency of strength. Both leads to poor displaying of the AMOLED display device. In view of such a problem, known techniques often adopt ultraviolet curable glue or Tuffy glue coated on the area of a display panel that is bonded with a flexible circuit board for protection of the flexible circuit board. However, homogeneity of large area of glue coating is hard to control and glue spilling may readily occur. In addition, due to constraints concerning coating thickness and constraints concerning glue strength, to ensure acceptable result of protection, the glue layer is often formed with a relatively large thickness and the property of flexing is affected.

### SUMMARY OF THE INVENTION

An objective of the present invention is to provide a flexible circuit board protection layer, which provides effective protection to a flexible circuit board and prevents the flexible circuit board from being damaged due to flexing.

Another objective of the present invention is to provide an organic light emitting display (OLED) device that involves a flexible circuit board protection layer to offer effective protection to a flexible circuit board and to prevent the flexible circuit board from being damaged due to flexing.

To achieve the above objectives, firstly, the present invention provides a flexible circuit board protection layer, which comprises a flexible backing, a first flexible layer arranged on one side of the flexible backing, and a second flexible layer arranged on one side of the first flexible layer that is distant from the flexible backing:

wherein the first flexible layer comprises a plurality of first strip sections that are arranged parallel and spaced from each other:

the second flexible layer comprises a plurality of second strip sections that are arranged parallel and spaced from each other; and

the first strip sections have an extension direction that is perpendicular to an extension direction of the second strip sections.

A material of the first flexible layer comprises at least one of glass fiber and non-woven fabric; and

a material of the second flexible layer comprises at least one of glass fiber and non-woven fabric.

A material of the flexible backing comprises an organic polymer material.

The first strip sections have a shape that is rectangular; the second strip sections have a shape that is rectangular.

The present invention also provides an OLED display device, which comprises a display panel and a flexible circuit board and two flexible circuit board protection layers that are arranged on one side of the display panel;

wherein the two flexible circuit board protection layers are respectively arranged on one side of the flexible circuit board that is adjacent to the display panel and one side of the flexible circuit board that is distant from the display panel.

Optionally, the first flexible layer of each of the flexible circuit board protection layer is arranged on one side of the flexible backing that is adjacent to the flexible circuit board.

Optionally, the first flexible layer of each of the flexible circuit board protection layer is arranged on one side of the flexible backing that is distant from the flexible circuit board.

Optionally, the first flexible layer of the flexible circuit board protection layer that is arranged on one side of the flexible circuit board that is distant from the display panel is arranged on one side of the flexible backing that is adjacent to the flexible circuit board; and

the first flexible layer of the flexible circuit board protection layer that is arranged on one side of the flexible circuit board that is adjacent to the display panel is arranged on one side of the flexible backing that is distant from the flexible circuit board.

Optionally, the first flexible layer of the flexible circuit board protection layer that is arranged on one side of the flexible circuit board that is distant from the display panel is arranged on one side of the flexible backing that is distant from the flexible circuit board; and

the first flexible layer of the flexible circuit board protection layer that is arranged on one side of the flexible circuit board that is adjacent to the display panel is arranged on one side of the flexible backing that is adjacent to the flexible circuit board.

Materials of the first flexible layers of the two flexible circuit board protection layers are different; and

materials of the second flexible layers of the two flexible circuit board protection layers are different.

The present invention further provides a flexible circuit board protection layer, which comprises a flexible backing, a first flexible layer arranged on one side of the flexible backing, and a second flexible layer arranged on one side of the first flexible layer that is distant from the flexible backing;

wherein the first flexible layer comprises a plurality of first strip sections that are arranged parallel and spaced from each other;

the second flexible layer comprises a plurality of second strip sections that are arranged parallel and spaced from each other; and

the first strip sections have an extension direction that is perpendicular to an extension direction of the second strip sections;

wherein a material of the first flexible layer comprises at least one of glass fiber and non-woven fabric; and

a material of the second flexible layer comprises at least one of glass fiber and non-woven fabric;

wherein a material of the flexible backing comprises an organic polymer material; and

wherein the first strip sections have a shape that is rectangular; the second strip sections have a shape that is rectangular.

The efficacy of the present invention is that the present invention provides a flexible circuit board protection layer, which comprises a flexible backing, a first flexible layer arranged on one side of the flexible backing, and a second flexible layer arranged on one side of the first flexible layer that is distant from the flexible backing. The first flexible layer comprises a plurality of first strip sections that are arranged parallel and spaced from each other. The second flexible layer comprises a plurality of second strip sections that are arranged parallel and spaced from each other. An extension direction of the first strip sections is perpendicular to an extension direction of the second strip sections. To use in an OLED display device, the flexible circuit board is arranged between two such flexible circuit board protection layers and then disposed at one side of a display panel in order to effectively protect the flexible circuit board and prevent the flexible circuit board from being damaged during flexing and also prevent the flexible circuit board from being damaged by an external force during fabrication and shipping of the OLED display device. The present invention provides an OLED display device, which uses a flexible circuit board protection layer to provide effective protection to a flexible circuit board in order to prevent the flexible circuit board from being damaged during flexing.

### BRIEF DESCRIPTION OF THE DRAWINGS

For better understanding of the features and technical contents of the present invention, reference will be made to the following detailed description of the present invention, in combination with the attached drawings. However, the drawings are provided only for reference and illustration and are not intended to limit the present invention.

In the drawings:

FIG. 1 is a top plan view showing a flexible circuit board protection layer according to the present invention;

FIG. 2 is a cross-sectional view taken along line A-A′ of FIG. 1,

FIG. 3 is a schematic view illustrating a structure of a first embodiment of an organic light emitting display (OLED) device according to the present invention:

FIG. 4 is a schematic view illustrating a structure of a second embodiment of the OLED display device according to the present invention;

FIG. 5 is a schematic view illustrating a structure of a third embodiment of the OLED display device according to the present invention; and

FIG. 6 is a schematic view illustrating a structure of a fourth embodiment of the OLED display device according to the present invention.

### DETAILED DESCRIPTION OF THE PREFERRED EMBODIMENTS

To further expound the technical solution adopted in the present invention and the advantages thereof, a detailed description will be given with reference to the preferred embodiments of the present invention and the drawings thereof.

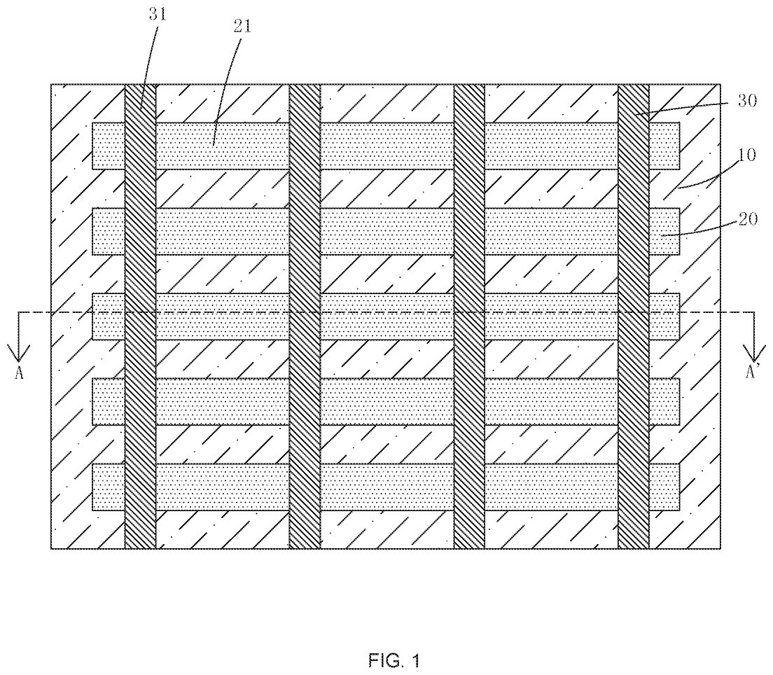

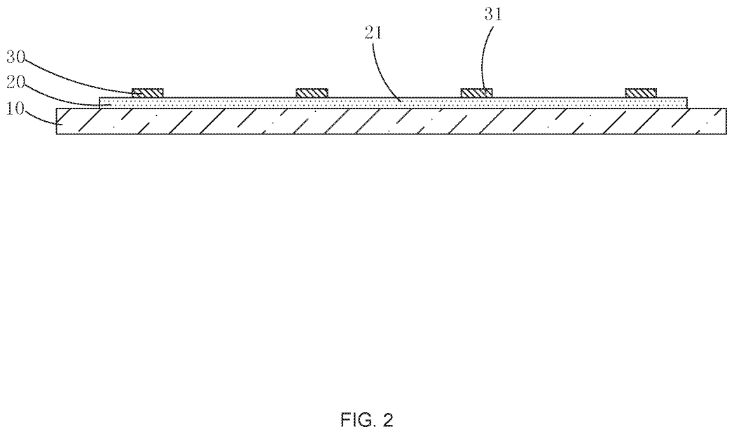

Referring to FIGS. 1 and 2, the present invention provides a flexible circuit board protection layer, which comprises a flexible backing 10, a first flexible layer 20 arranged on one side of the flexible backing 10, and a second flexible layer 30 arranged on one side of the first flexible layer 20 that is distant from the flexible backing 10.

The first flexible layer 20 comprises a plurality of first strip sections 21 that are arranged parallel and spaced from each other.

The second flexible layer 30 comprises a plurality of second strip sections 31 that are arranged parallel and spaced from each other.

The first strip sections 21 have an extension direction that is perpendicular to an extension direction of the second strip sections 31.

Specifically, a material of the first flexible layer 20 and a material of the second flexible layer 30 are both selected as materials having an excellent property of flexibility and easy machinability. For example, the material of the first flexible layer 20 can be, but not limited to, at least one of glass fiber and non-woven fabric. The material of the second flexible layer 30 can be, but not limited to, at least one of glass fiber and non-woven fabric.

Specifically, the material of the first flexible layer 20 and the material of the second flexible layer 30 can be identical or can be different. Further, strengths of the material of the first flexible layer 20 and the material of the second flexible layer 30 can be designed according the actual requirements of products.

Specifically, a material of the flexible backing 10 is selected as a material having an excellent property of flexibility and easy machinability and may be selected as an organic polymer material, such as a high temperature-resistant resin material, like polyimide (PI).

Specifically, a shape and a size of the first strip sections 21 and a shape and a size of the second strip sections 31 can be designed according to the desired property of flexibility of product. For example, in an embodiment shown in FIG. 1, the shape of the first strip sections 21 is rectangular; and the shape of the second strip sections 31 is also rectangular.

It is noted that in an application of the flexible circuit board protection layer according to the present invention to an organic light emitting display (OLED) device, a flexible circuit board is sandwiched between two such flexible circuit board protection layers of the present invention to form a three-layered structure. The three-layered structure is arranged in a flexible circuit board bonding area on one side of a display panel. The bonding area is a flexing area that is involved for realizing a slim frame. With such an arrangement of the first flexible layer 20 that comprises a plurality of first strip sections 21 and the second flexible layer 30 that comprises a plurality of the second strip sections 31 of which the extension direction is perpendicular to that of the first strip sections 21, the performance of flexing of the flexible circuit board protection layers and the flexible circuit board sandwiched between the flexible circuit board protection layers can be greatly improved by taking advantage of the property that the first flexible layer 20 and the second flexible layer 30 have different structural strengths. In addition, the flexible circuit board protection layers offer effective protection to the flexible circuit board in order to prevent the flexible circuit board from being damaged during flexing and thus enhance flexing performance of the flexible circuit board bonding area of the OLED display device and prevent the flexible circuit board from being damaged by an external force during fabrication and shipping processes of the OLED display device to thereby improve product quality.

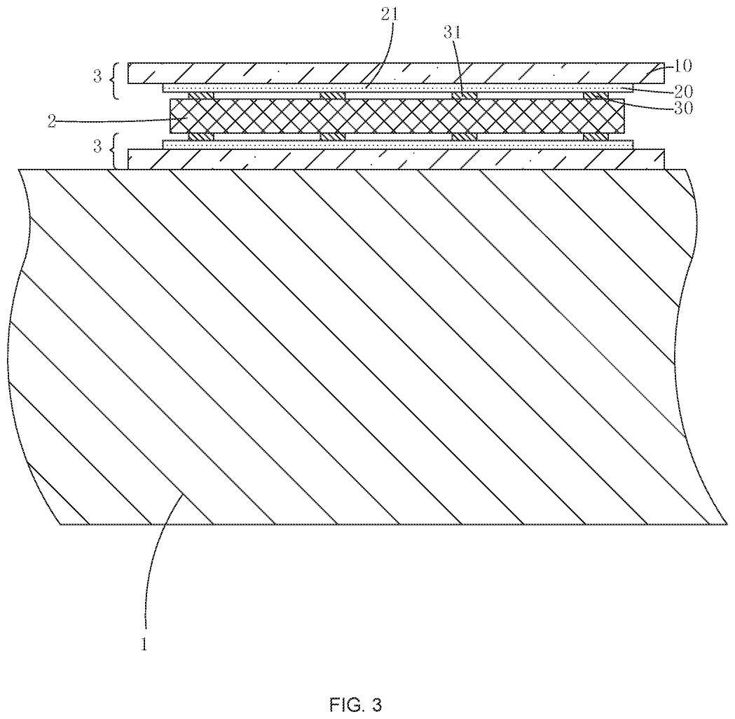

Based on the same inventive idea, the present invention also provides an OLED display device. Reference being had to FIG. 3, in combination with FIGS. 1 and 2, a first embodiment of the flexible display device according to the present invention is provided. The OLED display device of the present invention comprises a display panel 1, a flexible circuit board 2 arranged on one side of the display panel 1, and two flexible circuit board protection layers 3.

The two flexible circuit board protection layers 3 are respectively arranged on one side of the flexible circuit board 2 that is adjacent to the display panel 1 and one side thereof that is distant from the display panel 1.

Specifically, referring to FIGS. 1 and 2, the flexible circuit board protection layer 3 comprises a flexible backing 10, a first flexible layer 20 arranged on one side of the flexible backing 10, and a second flexible layer 30 arranged on one side of the first flexible layer 20 that is distant from the flexible backing 10.

The first flexible layer 20 comprises a plurality of first strip sections 21 that are arranged parallel to and spaced from each other.

The second flexible layer 30 comprises a plurality of second strip sections 31 that are arranged parallel to and spaced from each other.

The first strip sections 21 have an extension direction that is perpendicular to an extension direction of the second strip sections 31.

Specifically, a material of the first flexible layer 20 and a material of the second flexible layer 30 are both selected as materials having an excellent property of flexibility and easy machinability. For example, the material of the first flexible layer 20 can be, but not limited to, at least one of glass fiber and non-woven fabric. The material of the second flexible layer 30 can be, but not limited to, at least one of glass fiber and non-woven fabric.

Specifically, the material of the first flexible layer 20 and the material of the second flexible layer 30 can be identical or can be different. Further, strengths of the material of the first flexible layer 20 and the material of the second flexible layer 30 can be designed according the actual requirements of products.

Specifically, a material the flexible backing 10 is selected as a material having an excellent property of flexibility and easy machinability and may be selected as an organic polymer material, such as a high temperature-resistant resin material, like polyimide (PI).

Specifically, a shape and a size of the first strip sections 21 and a shape and a size of the second strip sections 31 can be designed according to the desired property of flexibility of product. For example, in an embodiment shown in FIG. 1, the shape of the first strip sections 21 is rectangular; and the shape of the second strip sections 31 is also rectangular.

Specifically, the display panel 1 comprises a flexible circuit board bonding area, which is a flexing area that is involved for realizing a slim frame. The flexible circuit board 2 and two flexible circuit board protection layers 3 provided on two sides thereof are arranged in the flexible circuit board bonding area.

Specifically, referring to FIG. 3, in a first embodiment of the OLED display device according to the present invention, the first flexible layer 20 of each of the flexible circuit board protection layers 3 is arranged on one side of the flexible backing 10 that is adjacent to the flexible circuit board 2 and the second flexible layer 30 of each of the flexible circuit board protection layers 3 is arranged on one side of the first flexible layer 20 that is adjacent to the flexible circuit board 2.

Specifically, the material of the first flexible layers 20 of the two flexible circuit board protection layers 3, the material of the second flexible layers 30, and the material of the flexible backing 10 could be the same or they could be different and adjustment can be made according to practical requirement of products.

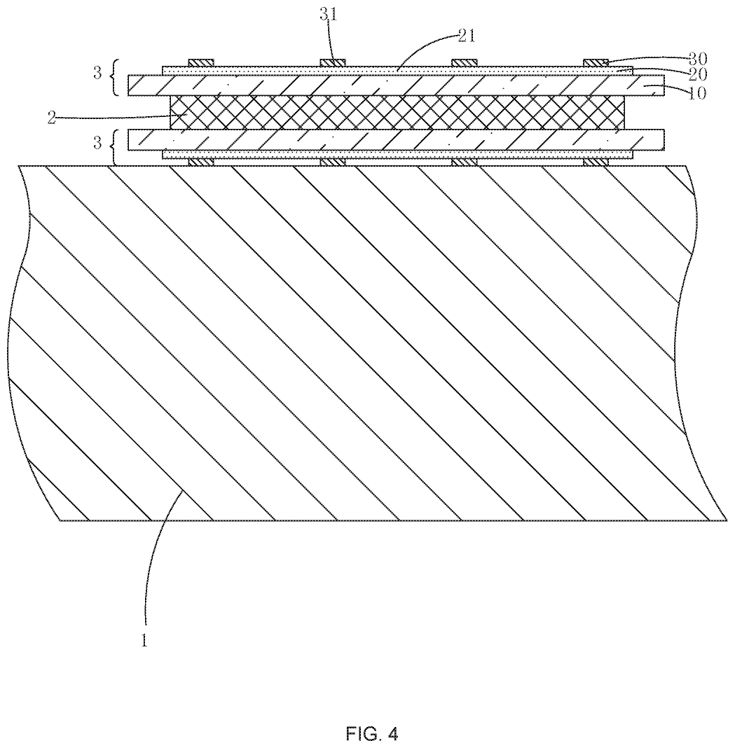

Referring to FIG. 4, a second embodiment of the OLED display device according to the present invention is shown. The second embodiment is different from the first embodiment in that the first flexible layer 20 of each of the flexible circuit board protection layer 3 is arranged on one side of the flexible backing 10 that is distant from the flexible circuit board 2 so that the second flexible layer 30 of each of the flexible circuit boards 3 is arranged on one side of the first flexible layer 20 that is distant from the flexible circuit board 2. The remaining is the same as the first embodiment and repeated description will be omitted.

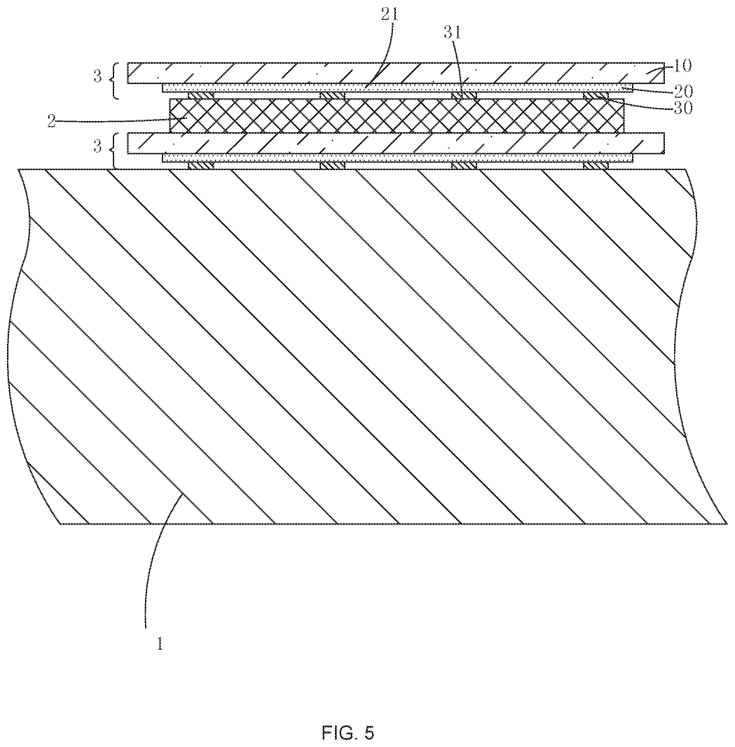

Referring to FIG. 5, a third embodiment of the OLED display device according to the present invention is shown. The third embodiment is different from the first embodiment in that the first flexible layer 20 of the flexible circuit board protection layer 3 that is arranged on one side of the flexible circuit board 2 that is adjacent to the display panel 1 is arranged on one side of the flexible backing 10 that is distant from the flexible circuit board 2 and thus, the second flexible layer 30 of the flexible circuit board protection layer 3 that is arranged on one side of the flexible circuit board 2 that is adjacent to the display panel 1 is arranged on one side of the flexible backing 10 that is distant from the flexible circuit board 2. The remaining is the same as the first embodiment and repeated description will be omitted.

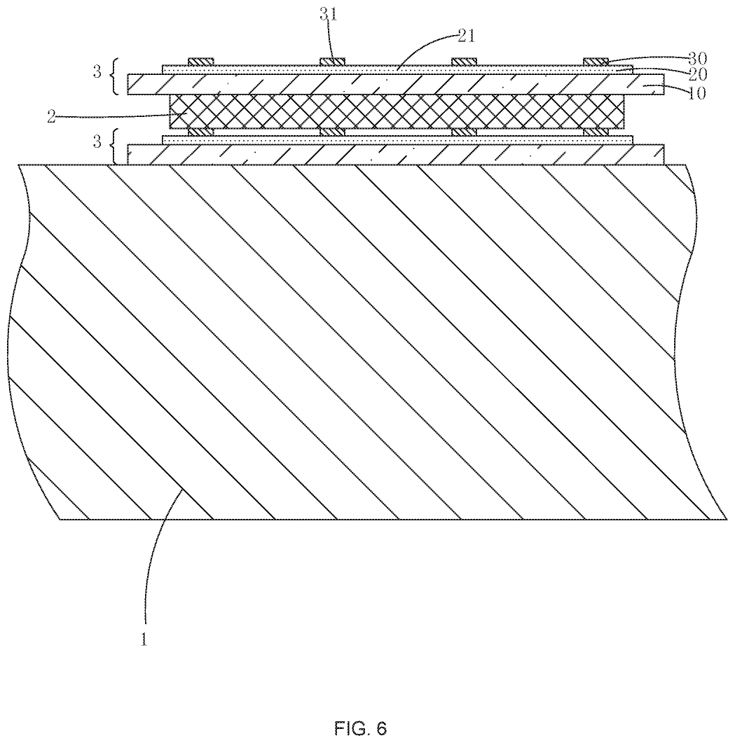

Referring to FIG. 6, a fourth embodiment of the OLED display device according to the present invention is shown. The fourth embodiment is different from the first embodiment in that the first flexible layer 20 of the flexible circuit board protection layer 3 that is arranged on one side of the flexible circuit board 2 that is distant from the display panel 1 is arranged on one side of the flexible backing 10 that is distant from the flexible circuit board 2 and thus, the second flexible layer 30 of the flexible circuit board protection layer 3 that is arranged on one side of the flexible circuit board 2 that is distant from the display panel 1 is arranged on one side of the flexible backing 10 that is distant from the flexible circuit board 2. The remaining is the same as the first embodiment and repeated description will be omitted.

It is noted that in an OLED display device of the present invention, a flexible circuit board 2 is sandwiched between two such flexible circuit board protection layers 3 to form a three-layered structure. The three-layered structure is arranged in a flexible circuit board bonding area on one side of a display panel 1. With such an arrangement of a first flexible layer 20 that comprises a plurality of first strip sections 21 and a second flexible layer 30 that comprises a plurality of the second strip sections 31 of which the extension direction is perpendicular to that of the first strip sections 21 in the flexible circuit board protection layer 3, the performance of flexing of the flexible circuit board protection layers 3 and the flexible circuit board 2 sandwiched between the flexible circuit board protection layers 3 can be greatly improved by taking advantage of the property that the first flexible layer 20 and the second flexible layer 30 have different structural strengths. In addition, the flexible circuit board protection layers 3 offer effective protection to the flexible circuit board 2 in order to prevent the flexible circuit board 2 from being damaged during flexing and thus enhance flexing performance of the flexible circuit board bonding area of the OLED display device and prevent the flexible circuit board 2 from being damaged by an external force during fabrication and shipping processes of the OLED display device to thereby improve product quality.

In summary, the present invention provides a flexible circuit board protection layer, which comprises a flexible backing, a first flexible layer arranged on one side of the flexible backing, and a second flexible layer arranged on one side of the first flexible layer that is distant from the flexible backing. The first flexible layer comprises a plurality of first strip sections that are arranged parallel and spaced from each other. The second flexible layer comprises a plurality of second strip sections that are arranged parallel and spaced from each other. An extension direction of the first strip sections is perpendicular to an extension direction of the second strip sections. To use in an OLED display device, the flexible circuit board is arranged between two such flexible circuit board protection layers and then disposed at one side of a display panel in order to effectively protect the flexible circuit board and prevent the flexible circuit board from being damaged during flexing and also prevent the flexible circuit board from being damaged by an external force during fabrication and shipping of the OLED display device. The present invention provides an OLED display device, which uses a flexible circuit board protection layer to provide effective protection to a flexible circuit board in order to prevent the flexible circuit board from being damaged during flexing.

Based on the description given above, those having ordinary skills in the art may easily contemplate various changes and modifications of the technical solution and the technical ideas of the present invention. All these changes and modifications are considered belonging to the protection scope of the present invention as defined in the appended claims.

What is claimed is:

1. A flexible circuit board protection layer, comprising a flexible backing, a first flexible layer arranged on one side of the flexible backing, and a second flexible layer arranged on one side of the first flexible layer that is distant from the flexible backing;
wherein the first flexible layer comprises a plurality of first strip sections that are arranged parallel and spaced from each other;
the second flexible layer comprises a plurality of second strip sections that are arranged parallel and spaced from each other; and
the first strip sections have an extension direction that is perpendicular to an extension direction of the second strip sections.

2. The flexible circuit board protection layer according to claim 1, wherein a material of the first flexible layer comprises at least one of glass fiber and non-woven fabric; and
a material of the second flexible layer comprises at least one of glass fiber and non-woven fabric.

3. The flexible circuit board protection layer according to claim 1, wherein a material of the flexible backing comprises an organic polymer material.

4. The flexible circuit board protection layer according to claim 1, wherein the first strip sections have a shape that is rectangular; the second strip sections have a shape that is rectangular.

5. An organic light emitting display (OLED) device, comprising a display panel and a flexible circuit board and two of the flexible circuit board protection layer according to claim 1 that are arranged on one side of the display panel;
wherein the two flexible circuit board protection layers are respectively arranged on one side of the flexible circuit board that is adjacent to the display panel and one side of the flexible circuit board that is distant from the display panel.

6. The OLED display device according to claim 5, wherein the first flexible layer of each of the flexible circuit board protection layer is arranged on one side of the flexible backing that is adjacent to the flexible circuit board.

7. The OLED display device according to claim 5, wherein the first flexible layer of each of the flexible circuit board protection layer is arranged on one side of the flexible backing that is distant from the flexible circuit board.

8. The OLED display device according to claim 5, wherein the first flexible layer of the flexible circuit board protection layer that is arranged on one side of the flexible circuit board that is distant from the display panel is arranged on one side of the flexible backing that is adjacent to the flexible circuit board; and
the first flexible layer of the flexible circuit board protection layer that is arranged on one side of the flexible circuit board that is adjacent to the display panel is arranged on one side of the flexible backing that is distant from the flexible circuit board.

9. The OLED display device according to claim 5, wherein the first flexible layer of the flexible circuit board protection layer that is arranged on one side of the flexible circuit board that is distant from the display panel is arranged on one side of the flexible backing that is distant from the flexible circuit board; and
the first flexible layer of the flexible circuit board protection layer that is arranged on one side of the flexible circuit board that is adjacent to the display panel is arranged on one side of the flexible backing that is adjacent to the flexible circuit board.

10. The OLED display device according to claim 5, wherein materials of the first flexible layers of the two flexible circuit board protection layers are different; and
materials of the second flexible layers of the two flexible circuit board protection layers are different.

11. A flexible circuit board protection layer, comprising a flexible backing, a first flexible layer arranged on one side of the flexible backing, and a second flexible layer arranged on one side of the first flexible layer that is distant from the flexible backing;
wherein the first flexible layer comprises a plurality of first strip sections that are arranged parallel and spaced from each other;
the second flexible layer comprises a plurality of second strip sections that are arranged parallel and spaced from each other; and
the first strip sections have an extension direction that is perpendicular to an extension direction of the second strip sections;
wherein a material of the first flexible layer comprises at least one of glass fiber and non-woven fabric; and
a material of the second flexible layer comprises at least one of glass fiber and non-woven fabric:
wherein a material of the flexible backing comprises an organic polymer material; and
wherein the first strip sections have a shape that is rectangular; the second strip sections have a shape that is rectangular.
